(19) United States
(12) Patent Application Publication
(10) Pub. No.: US 2023/0121888 A1
(43) Pub. Date: Apr. 20, 2023

(54) SEMICONDUCTOR PACKAGE

(71) Applicant: SAMSUNG ELECTRONICS CO., LTD., SUWON-SI (KR)

(72) Inventors: Minsoo KIM, Hwaseong-si (KR); Jiho KIM, Suwon-si (KR); Unbyoung KANG, Hwaseong-si (KR); Sangsick PARK, Hwaseong-si (KR); Teakhoon LEE, Hwaseong-si (KR)

(21) Appl. No.: 17/884,695

(22) Filed: Aug. 10, 2022

(30) Foreign Application Priority Data
Oct. 14, 2021 (KR) 10-2021-0136654

(51) Int. Cl. H01L 25/065; H01L 23/367; H01L 23/498; H01L 23/00

(52) U.S. Cl. CPC H01L 25/0657; H01L 23/367; H01L 23/49816; H01L 24/05; H01L 24/16; H01L 24/73; H01L 2224/0557; H01L 2224/16135; H01L 2224/16227; H01L 2224/73251

(57) ABSTRACT

A semiconductor package includes a first semiconductor chip including upper signal pads and upper dummy pads. A second semiconductor chip is on the first semiconductor chip, and includes lower signal pads and lower dummy pads. First conductive bumps are between the upper signal pads and the lower signal pads. Second conductive bumps are between the upper dummy pads and the lower dummy pads. The upper dummy pads include merged pads covering a plurality of adjacent lower dummy pads. A plurality of metal plating layers are disposed on each of the merged pads in areas respectively corresponding to the plurality of adjacent lower dummy pads. The second conductive bumps include a plurality of conductive bumps respectively disposed between the plurality of first metal plating layers and the plurality of adjacent lower dummy pads.

### CROSS-REFERENCE TO RELATED APPLICATION(S)

This application claims the benefit under 35 USC 119 to Korean Patent Application No. 10-2021-0136654, filed on Oct. 14, 2021 in the Korean Intellectual Property Office, the disclosure of which is incorporated by reference in its entirety herein.

### 1. TECHNICAL FIELD

The present inventive concept relates to a semiconductor package.

### 2. DISCUSSION OF RELATED ART

Electronic devices have become increasingly miniaturized and lightweight as the electronics industry has developed and in view of consumer demands for such devices. Accordingly, semiconductor packages used in electronic devices increasingly provide high performance and high capacity characteristics along with miniaturization and a reduced weight. Semiconductor chips including through electrodes (e.g., through vias, TSVs) and a semiconductor package in which the semiconductor chips are stacked have been continuously researched and developed to implement high performance and high capacity along with miniaturization and weight reduction.

### SUMMARY

Embodiments of the present inventive concept provide a stacked semiconductor package having increased heat dissipation performance.

According to an embodiment of the present inventive concept, a semiconductor package includes a first semiconductor chip having an upper surface including first upper signal pads and first upper dummy pads disposed thereon, a lower surface including first lower signal pads and first lower dummy pads disposed thereon, and first through electrodes electrically connecting the first upper signal pads and the first lower signal pads. A second semiconductor chip is disposed on the first semiconductor chip. The second semiconductor chip has an upper surface including second upper signal pads and second upper dummy pads disposed thereon, a lower surface including second lower signal pads and second lower dummy pads disposed thereon, and second through electrodes electrically connecting the second upper signal pads and the second lower signal pads. First conductive bumps are respectively disposed between the first upper signal pads and the second lower signal pads. Second conductive bumps are respectively disposed between the first upper dummy pads and the second lower dummy pads. The first upper dummy pads include merged pads covering a plurality of adjacent second lower dummy pads among the second lower dummy pads. A plurality of first metal plating layers are disposed on an upper surface of each of the merged pads in areas respectively corresponding to the plurality of adjacent second lower dummy pads. The second conductive bumps include a plurality of conductive bumps respectively disposed between the plurality of first metal plating layers and the plurality of adjacent second lower dummy pads.

According to an embodiment of the present inventive concept, a semiconductor package includes a first semiconductor chip comprising an upper surface including upper signal pads and upper dummy pads disposed thereon, a lower surface including first lower signal pads and first lower dummy pads disposed thereon, and through electrodes electrically connecting the upper signal pads and the first lower signal pads. A second semiconductor chip is disposed on the first semiconductor chip, and comprises a lower surface including second lower signal pads and second lower dummy pads disposed thereon. Conductive bumps are respectively disposed between the upper signal pads and the second lower signal pads and are respectively disposed between the upper dummy pads and the second lower dummy pads. A non-conductive adhesive layer is disposed between the first semiconductor chip and the second semiconductor chip and surrounds the conductive bumps. The upper dummy pads comprise merged pads covering a plurality of adjacent second lower dummy pads among the second lower dummy pads and non-merged pads respectively covering only one second lower dummy pad among the second lower dummy pads. The merged pads are disposed in corner areas adjacent to each corner of the upper surface of the first semiconductor chip, and the non-merged pads are disposed between the corner areas on the upper surface of the first semiconductor chip.

According to an embodiment of the present inventive concept, a semiconductor package includes first and second substrates that are vertically stacked. A semiconductor device layer is disposed on a lower surface of the second substrate and faces an upper surface of the first substrate. Through electrodes penetrate through the second substrate and are respectively connected to the upper signal pads. Lower signal pads are disposed on a lower surface of the semiconductor device layer and are electrically connected to the through electrodes, respectively. Lower dummy pads are disposed on the lower surface of the semiconductor device layer. Upper signal pads are disposed on the upper surface of the first substrate and are arranged to correspond to each of the lower signal pads. Upper dummy pads are disposed on the upper surface of the first substrate and respectively cover a plurality of adjacent lower dummy pads among the lower dummy pads. A plurality of metal plating layers is disposed in areas respectively corresponding to the plurality of adjacent lower dummy pads in the respective upper dummy pads. First conductive bumps electrically connect the lower signal pads and the upper signal pads, respectively. Second conductive bumps are respectively disposed on the plurality of metal plating layers of the respective upper dummy pads and respectively connected to the lower dummy pads.

### BRIEF DESCRIPTION OF DRAWINGS

The above and other aspects, features, and advantages of embodiments of the present inventive concept will be more clearly understood from the following detailed description, taken in conjunction with the accompanying drawings, in which:

FIG. 1 is a cross-sectional view illustrating a semiconductor package according to an embodiment of the present inventive concept.

FIG. 2 is a plan view illustrating a semiconductor chip employed in the semiconductor package of FIG. 1 according to an embodiment of the present inventive concept.

FIG. 3 is a partially enlarged cross-sectional view illustrating portion “A1” of FIG. 1 according to an embodiment of the, present inventive concept.

FIG. 4 is a partially enlarged cross-sectional view illustrating portion “B of FIG. 3.

FIG. 5 is a partially enlarged plan view illustrating portion “A2” of FIG. 2.

FIGS. 6A to 6C are plan views illustrating various examples of merged pads that may be employed according to embodiments of the present inventive concept.

FIG. 7 is a plan view illustrating a semiconductor chip that may be employed in a semiconductor package according to an embodiment of the present inventive concept.

FIGS. 8A and 8B are plan views illustrating a semiconductor chip that may be employed in a semiconductor package according to embodiments of the present inventive concept.

FIG. 9 is a cross-sectional view illustrating a semiconductor package according to an embodiment of the present inventive concept.

FIGS. 10A to 10F are partially enlarged cross-sectional views illustrating portion “A1” of FIG. 1 for explaining a method of manufacturing a semiconductor package according to embodiments of the present inventive concept.

### DETAILED DESCRIPTION OF EMBODIMENTS

Hereinafter, embodiments of the present inventive concept will be described with reference to the accompanying drawings.

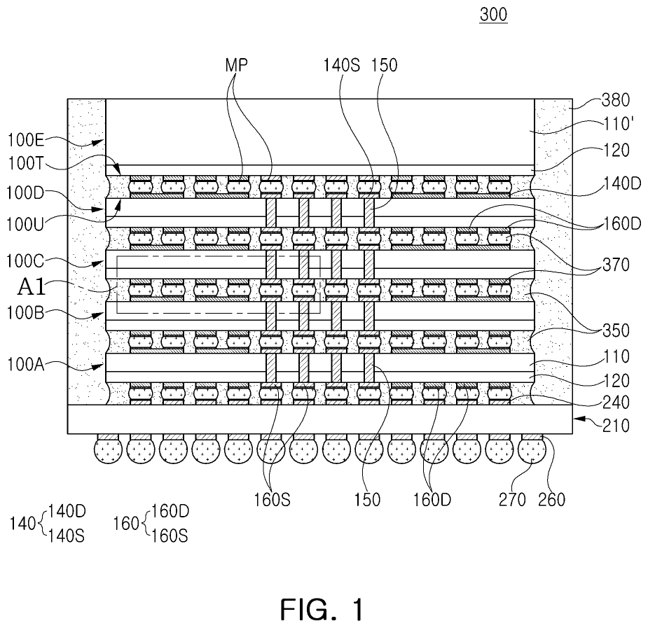

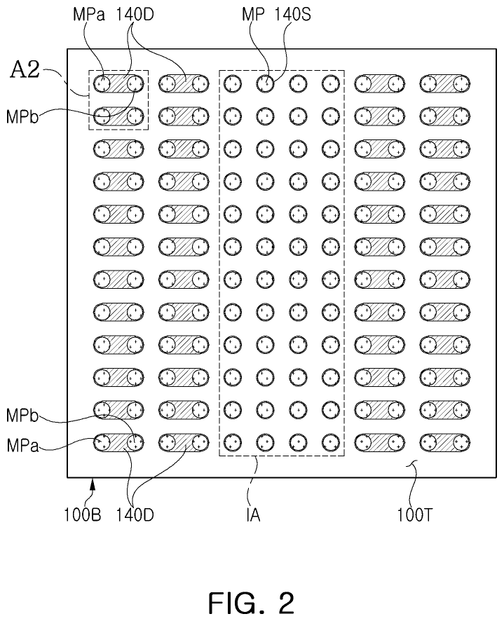

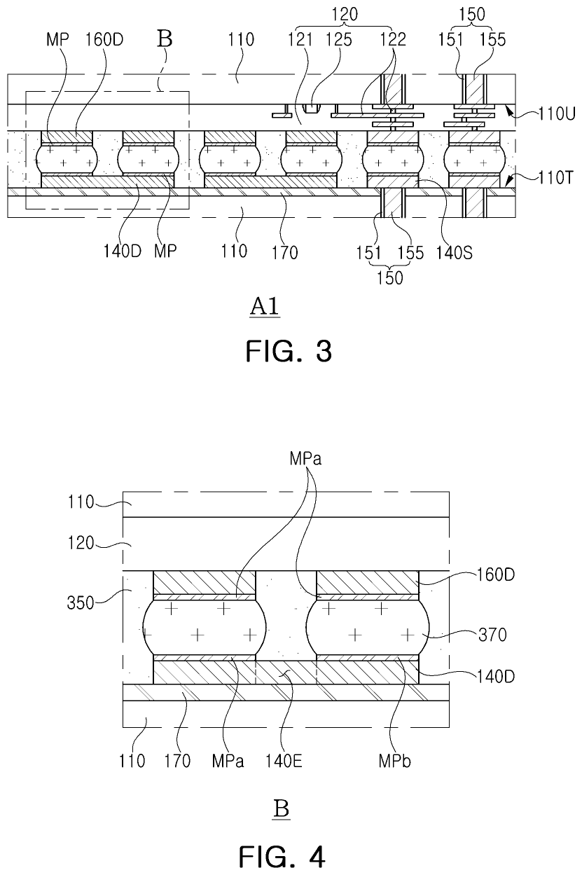

FIG. 1 is a cross-sectional view illustrating a semiconductor package according to an embodiment of the present inventive concept, FIG. 2 is a plan view illustrating a semiconductor chip employed in the semiconductor package of FIG. 1., and FIG. 3 is a partially enlarged view illustrating portion “A1” of FIG. 1.

Referring to an embodiment of FIG. 1, a semiconductor package 300 may include a first semiconductor chip 100A, a second semiconductor chip 100B, a third semiconductor chip 100C, a fourth semiconductor chip 100D and a fifth semiconductor chip 100E which are stacked in a vertical direction. The first to fifth semiconductor chips 100A to 100E may be disposed on a base substrate 210.

Each of the first to fifth semiconductor chips 100A, 100B, 100C, 100D, and 100E may have a lower surface (or referred to as a ‘first surface’) and an upper surface (also referred to as a ‘second surface’) that are opposite to each other (e.g. in the vertical direction), and the first to fifth semiconductor chip 100A, 100B, 100C, 100D, and 100E may be stacked so that different surfaces (e.g., the first surface and the second surface) face each other. Each of the first to fifth semiconductor chips 100A to 100E may include a semiconductor substrate 110, a semiconductor device layer 120, a through electrode 150, upper pads 140, and lower pads 160. However, as shown in an embodiment of FIG. 1, the semiconductor chip (e.g., the fifth semiconductor chip 100E) disposed at the uppermost level may not include the through electrode 150 and the upper pads 140.

The upper pads 140 are disposed on an upper surface 100T of each semiconductor chip, and include upper signal pads 140S and upper dummy pads 140D. Similarly, the lower pads 160 are disposed on a lower surface 100U of each semiconductor chip, and include lower signal pads 160S and lower dummy pads 160D. The upper signal pads 140S and the lower signal pads 160S may be electrically connected to each other by the through electrode 150. The through electrode 150 may extend from an upper surface to a lower surface of the semiconductor substrate 110, and may extend into the semiconductor device layer 120. In an embodiment, at least a portion of the through electrode 150 may have a column shape. The through electrode 150 may include a via plug 155 and a side insulating layer 151 surrounding the via plug 155. The side insulating layer 151 may electrically separate the via plug 155 from the semiconductor substrate 110 and the semiconductor device layer 120.

In a plan view, an area in which the upper signal pads 140S and the lower signal pads 160S are formed may be distinguished from an area in which the upper dummy pads 140D and the lower dummy pads 160D are formed. As illustrated in an embodiment of FIG. 2., the upper signal pads 140S and the lower signal pads 160S may be arranged in an inner area IA, and the upper dummy pads 140D and the lower dummy pads 160D may be arranged in two separate areas adjacent to both side corners of the semiconductor package 300. However, embodiments of the present inventive concept are not necessarily limited thereto. For example, in an embodiment the upper dummy pads 140D and the lower dummy pads 160D may be arranged in an area adjacent to four corners.

The upper dummy pads 1401 and the lower dummy pads 160D may include the same material as the upper signal pads 140S and the lower signal pads 160S, respectively. For example, the upper pads 140 and the lower pads 160 may include nickel (Ni) or copper (Cu). As described above, the upper signal pads 140S may be configured to tie connected to the through electrode 150, and the lower signal pads 160S may be disposed on a lower surface of the semiconductor device layer 120 to be connected to a wiring structure 122 (see FIG. 3), The upper dummy pads 1400 and the lower dummy pads 160D may be utilized as pads to increase heat dissipation performance while increasing alignment accuracy of the first to fifth semiconductor chips 100A to 100E.

The upper signal pads 140S and the lower signal pads 160S may be connected to internal circuits (e.g., the through electrode 150) of the first to fifth semiconductor chips 100A, 100B, 100C, 100D, and 100E, and may be provided as paths for a control signal, a power signal, a ground signal, and/or a data signal between the first to fifth semiconductor chips 100A, 100B, 100C, 100D, and 100E.

In a plan view, the upper signal pads 140S and the lower signal pads 160S may have a circular shape (see FIG. 2). However, embodiments of the present inventive concept are not necessarily limited thereto, and the upper and lower signal pads 140S, 1605 may have various other polygonal shapes, such as a square shape, a hexagon shape, etc.

Referring to an embodiment of FIG. 1, the upper signal pads 140S and the upper dummy pads 140D of one of the semiconductor chips 100A, 100B, 100C, and 100D may be respectively connected to the lower signal pads 160S and the lower dummy pads 160D of the other adjacent semiconductor chips 100B, 100C, 100D, and 100E located on one of the semiconductor chips 100A, 100B, 100C, and 100D by conductive bumps 370.

In an embodiment, the upper dummy pads 140D may be a merged pad configured to cover a plurality of adjacent lower dummy pads 160D among the lower dummy pads 160D. For example, referring to embodiments of FIGS. 2 and 3, the upper dummy pads 140D have an area capable of covering (e.g., overlapping in the vertical direction) two adjacent lower dummy pads 160D and may be formed on locations corresponding to the corresponding lower dummy pads 160D.

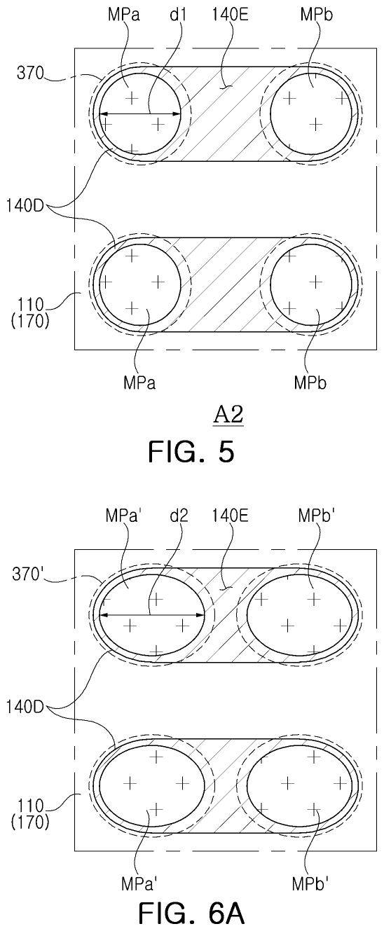

As illustrated in embodiments of FIGS. 2 and 5, the upper dummy pads 140D may be provided as a merged pad having an area larger than that of a normal single pad by an expanded area 140E. In an embodiment in which the upper dummy pads 140D are replaced with the merged pad, the total pad area on the upper surface 100T of the semiconductor chip may he increased in a range of about 1.5 to about 2.5 times as compared to an embodiment in which a usual single pad having an area substantially corresponding to a single lower pad, such as a lower dummy pad 160D is employed. As described above, the volume of a pad having excellent thermal conductivity may be increased by employing the merged pad, and as a result, the heat dissipation performance in the space between semiconductor chips may be increased.

Also, referring to embodiments of FIGS. 3, 4, and 5, metal plating layers MPa, MPb, and MP may be formed on the upper pads 140 and the lower pads 160, respectively. FIG. 4 is a partially enlarged view illustrating an enlarged part “B” of FIG. 3, and FIG. 5 is a partially enlarged view illustrating air enlarged part “A2” of FIG. 2.

Each of the metal plating layers MPa, MPb, and MP may define a joint area by the conductive bump 370 in a pad area. For example, in an embodiment, the metal plating layers MPa, MPb and MP may include gold (Au).

In an embodiment, one metal plating layer MP may be disposed on each of the lower dummy pads 160D, the upper signal pads 140S, and the lower signal pads 160S, and may have an area approximately corresponding to the pad area. As shown in embodiments of FIGS. 4 and 5, a plurality of metal plating layers MPa and MPb may be disposed on an upper surface of each of the upper dummy pads 140D. The plurality of metal plating layers MPa and MPb may be respectively disposed in areas corresponding to the two adjacent lower dummy pads 160D.

The two metal plating layers MPa and MPb may be disposed separately from each other on the respective corresponding upper dummy pads 140D. The plurality of separated metal plating layers MPa and MPb may prevent the two conductive bumps 370 of the lower dummy pads 160D from being merged. For example, the plurality of separated metal plating layers MPa and MPb may maintain the conductive bumps 370 of a constant volume at a desired position even on an expanded pad like the upper dummy pads 140D which includes the expanded area 140E, thereby providing a stable connection between adjacent semiconductor chips by the conductive bumps 370.

Referring to embodiments of FIGS. 1 and 3, each of the first to fifth semiconductor chips 100A, 100B, 100C, 100D, and 100E may include the semiconductor substrate 110 and the semiconductor device layer 120 disposed on a lower surface of the semiconductor substrate 110.

The semiconductor device layers 120 may include a plurality of individual devices 125 disposed on the lower surface 110U of the semiconductor substrate 110, the insulating layer 121 disposed on the lower surface 110U of the semiconductor substrate 110, and a wiring structure 122 formed on the insulating layer 121. The wiring structure 122 may have a multilayer structure including a wiring layer and a via. The wiring structure 122 may be connected to the plurality of individual devices 125 or other wirings (e.g., the through electrode 150), and the lower signal pad 160S may be electrically connected to the wiring structure 122 on the lower surface 100U of the first to fifth semiconductor chips 100A, 100B, 100C, 100D, and 100E.

In an embodiment, the first to fourth semiconductor chips 100A, 100B, 100C, and 100D may respectively include upper insulating layers 170 disposed on the upper surface 110T of the semiconductor substrate 110. The upper insulating layer 170 may have an upper surface substantially flat to an upper surface of the through electrode 150. The upper signal pads 140S and the upper dummy pads 140D may be disposed on the upper insulating layer 170. For example, the upper insulating layer 170 may include silicon oxide. In some embodiments, as described above, the fifth semiconductor chip 100E does not include the through electrode 150, and a semiconductor substrate 110 of the fifth semiconductor chip 100E may have a thickness (e.g., length in the vertical direction) that is greater than a thickness of the other semiconductor chips.

Also, the first to fifth semiconductor chips 100A, 100B, 100C, 100D, and 100E may be attached to each other by the non-conductive films 350. The non-conductive films 350 may be disposed between adjacent semiconductor chips of the first to fifth semiconductor chips 100A, 100B, 100C, 100D, and 100E and between the base substrate 210 and the first semiconductor chip 100A. The non-conductive films 350 may be formed to surround conductive bumps. For example, the non-conductive films 350 may be adhered to the stacked semiconductor chips 100A, 100B, 100C, 100D, and 100E. The non-conductive films 350 may include an adhesive resin. The adhesive resin may be a thermosetting resin. In an embodiment, the adhesive resin may include, for example, at least one material selected from a bisphenol-type epoxy resin, a novolak-type epoxy resin, a phenol resin, a urea resin, a melamine resin, an unsaturated polyester resin, and a resorcinol resin. In an embodiment as shown in FIG. 1, the non-conductive films 350 may have concave side surfaces recessed inward compared to side surfaces of the adjacent semiconductor chips 100A, 100B, 100C, 100D, and 100E. Such a shape may increase bonding strength with a molding member 380 or prevent defects in a process after stacking semiconductor chips.

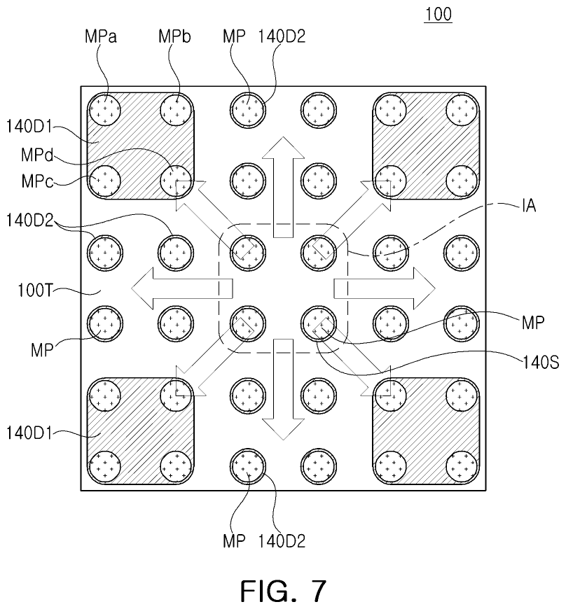

In addition, in an embodiment, the merged pad employed as the upper dummy pads 140D has a volume larger than that of a usual pad by the expanded area 140E, and thus the space between the semiconductor chips may be reduced. The space between the semiconductor chips may be reduced, and thus a filling factor may be increased by the non-conductive film 350. For example, the merged pad may be selectively disposed in a space where the non-conductive films 350 is vulnerable to filling, and thus not only the heat dissipation performance may be increased, but also uniform filling may be ensured in the space between the semiconductor chips, thereby promoting a connection stability between chips (see FIG. 7).

In an embodiment, the first to fifth semiconductor chips 100A 100B, 100C, 100D, and 100E may be memory chips or logic chips. For example, the first to fifth semiconductor chips 100A, 100B, 100C, 100D, and 100E may all be the same type of memory chips, and in another example, some of the first to fifth semiconductor chips 100A, 100B, 100C, 100D, and 100E may be memory chips, and others may be logic chips.

For example, in an embodiment, the memory chip may be a volatile memory chip such as dynamic random access memory (DRAM) or static random access memory (SRAM) or a non-volatile memory chip such as phase-change random access memory (PRAM), magnetoresistive random access memory (MRAM), ferroelectric random access memory (FeRAM) or resistive random access memory (RRAM). In some embodiments, the first to fifth semiconductor chips 100A, 100B, 100C, 100D, and 100E may be high bandwidth memory (HBM) DRAMs.

Also, the logic chip may be, for example, a microprocessor, an analog device, or a digital signal processor.

In some embodiments, the semiconductor substrate 110 may include silicon. In some embodiments, the semiconductor substrate 110 may include a semiconductor element such as germanium, or a compound semiconductor such as silicon carbide (SiC), gallium arsenide (GaAs), indium arsenide (InAs), and indium phosphide (InP). Alternatively, the semiconductor substrate 110 may have a silicon on insulator (SOI) structure. For example, the semiconductor substrate 110 may include a buried oxide layer (BOX). The semiconductor substrates 110 may include a conductive area, for example, a well doped with an impurity or a structure doped with an impurity. In addition, the semiconductor substrate 110 may have various device isolation structures such as a shallow trench isolation (STI) structure.

In an embodiment of FIG. 1, a semiconductor package 300A in which the first to fifth semiconductor chips 100A, 100B, 100C, 100D, and 100E are stacked is exemplified. However, embodiments of the present inventive concept are not necessarily limited thereto and the number of semiconductor chips stacked in the semiconductor package 300 may vary. For example, two, three, four or more than five semiconductor chips (e.g., eight) may be stacked in the semiconductor package 300.

The first to fifth semiconductor chips 100A 100B, 100C, 100D, and 100E may be the same chip and may have the same area as illustrated in an embodiment of FIG. 1. In some embodiments, the first to fifth semiconductor chips 100A, 100B, 100C, 100D, and 100E may have different areas from each other. All side surfaces of semiconductor chips may not be arranged to be substantially on the same plane (e.g., aligned in the vertical direction), but may at least partially have a stepped arrangement.

The semiconductor package 300 according to an embodiment further includes a base substrate 210, and as described above, the first to fifth semiconductor chips 100A, 100B, 100C, 100D, and 100E may be stacked vertically on the base substrate 210. The base substrate 210 may be, for example, an interposer for redistribution. In an embodiment in which the base substrate 210 is an interposer, the base substrate 210 may include a silicon substrate having a first pad 240 and a second pad 260. An internal wiring connecting the first pad 240 and the second pad 260 may be formed in the base substrate 210. A connection bump 270 may be attached to the second pad 260 located on a lower surface of the base substrate 210. In an embodiment, the connection bump 270 may be, for example, a solder ball or a conductive bump.

The molding member 380 may surround side surfaces of the first to fifth semiconductor chips 100A, 100B, 100C, 100D, and 100E and side surfaces of the non-conductive films 350. In some embodiments, the molding member 380 may cover an upper surface of the fifth semiconductor chip 100E. In some embodiments, the molding member 380 may be omitted (see FIG. 5) or the upper surface of the fifth semiconductor chip 100E may be exposed to the outside. In an embodiment, the molding member 380 may include an epoxy mold compound (EMC), etc.

As described above, the semiconductor package 300 according to an embodiment may provide the upper dummy pad 140D disposed on the upper surface 100T of each semiconductor chip as a merged pad in which two or more pads are merged, thereby increasing heat dissipation performance. In addition, the plurality of metal plating layers MPa and MPb respectively corresponding to the plurality of lower dummy pads 160D may be disposed on the merged pad, thereby preventing a plurality of conductive bumps provided on the expanded merged pad from merging with each other, and providing a stable connection structure by maintaining the arrangement of the conductive bumps 370.

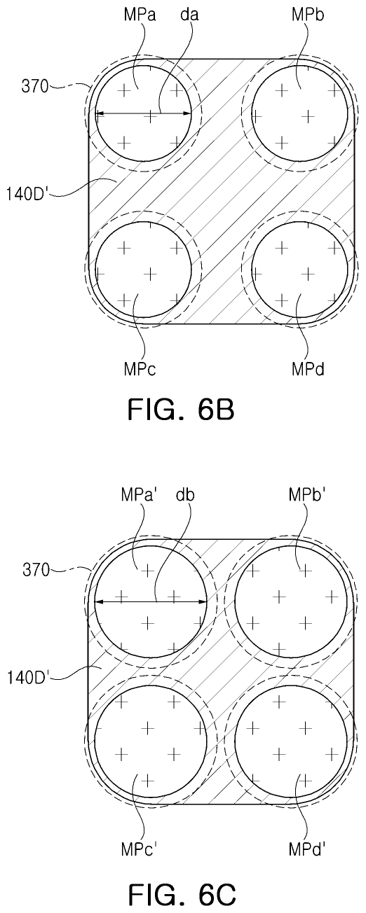

As illustrated in an embodiment of FIG. 5, the upper dummy pads 140D is configured to respectively cover the two lower dummy pads 160D. However, embodiments of the present inventive concept are not necessarily limited thereto and the upper dummy pads 140D may be configured to cover a different number of lower dummy pads 160D (see FIGS. 6B and 6C).

In addition, the metal plating layers MPa and MPb located on the upper dummy pad 140D is configured to have substantially the same size d1 as that of the metal plating layer MP located on another pad (e.g., an upper signal pad or a dummy pad that is not merged). However, embodiments of the present inventive concept are not necessarily limited thereto and in some embodiments, an area of the metal plating layer located on the upper dummy pad 140D may be expanded (see FIGS. 6A and 6C). Various embodiments of the merged pad are illustrated in FIGS. 6A to 6C.

First, referring to an embodiment of FIG. 6A, similar to the merged pad included in an embodiment of FIG. 5, the two merged pads 140D are shown. Each merged pad 140D is configured to cover two adjacent lower dummy pads 160D (see FIG. 4), and includes two metal plating layers MPa′ and MPb′ respectively corresponding to two adjacent lower dummy pads.

However, the metal plating layers MPa′ and MPb′ in an embodiment of FIG. 6A are formed to have a size d2 greater than the size d1 of the metal plating layers MPa and MPb of an embodiment of FIG. 5. Even in an embodiment in which the size of the metal plating layers MPa′ and MPb′ is increased, the metal plating layers MPa′ and MPb′ have a sufficient space so that the conductive bumps 370′ (indicated by a dotted line) respectively formed on the metal plating layers MPa′ and MPb′ are not merged during a bonding process. The conductive bumps 370′ in an embodiment of FIG. 6A may also be formed to have a relatively large volume similar to the expanded metal plating layers MPa′ and MPb′. In an embodiment including the conductive bumps 370′ having a relatively large volume, a space to be filled by the non-conductive film may also be reduced between the semiconductor chips.

Here, unlike the merged pad 140D employed in an embodiment of FIG. 5, single pads that are not merged so that the pad covers (e.g., overlaps in a vertical direction) only one lower dummy pad 160D may be referred to as “non-merged pads”, like the upper and lower signal pads (e.g., 140S and 160S in FIG. 2) or the dummy pad that are not merged (e.g., 160D in FIG. 3).

In an embodiment of FIG. 6A, the expanded metal plating layers MPa′ and MPb′ may have an area larger than that of the metal plating layer on the other pad, that is, the non-merged pad. Also, the expanded metal plating layers MPa′ and MPb′ may be included, and thus the conductive bumps 370′ to be formed on the merged pad 140D may have a volume larger than that of the conductive bumps on the other pad, e.g., the non-merged pad.

Referring, to an embodiment of FIG. 6B, unlike an embodiment of FIG. 6A, the merged pad is configured to cover four adjacent lower dummy pads, and includes four metal plating lavers MPa, MPb, MPc, and MPd respectively corresponding to the four adjacent lower dummy pads. The four adjacent lower dummy pads may be arranged in a square (2×2 arrangement) in a plan view.

The upper dummy pad is provided as the merged pad 140D′ corresponding to four single pads, and thus the pad area may be further expanded as compared to the merged pad 140D corresponding to two pads as shown in an embodiment of FIGS. 5 and 6A. For example, in an embodiment that includes the merged pad 140D corresponding to two pads, a pad area increase in a range of about 1.5 to about 1.8 times may be expected as compared to an embodiment of a single pad. In contrast, an embodiment that includes the merged pad 140D′ corresponding to four pads as shown in FIG. 6B, a pad area increase in a range of about 2 to about 2.5 times may be expected. In some embodiments, the upper dummy pad may be provided as the merged pad 140D′ corresponding to a different number of pads. For example, the upper dummy pad may be provided as merged pad corresponding to various arrangements such as an arrangement of 6 (3×2 or 2×3), an arrangement of 8 (4×2 or 2×4), or an arrangement of 9 (3×3). However, embodiments of the present inventive concept are not necessarily limited thereto.

Referring to an embodiment of FIG. 6C, similar to the merged pad employed in an embodiment of FIG. 6B, the merged pad 140D′ is configured to cover four adjacent lower dummy pads (see 160D in FIG. 4). However, the metal plating layers MPa′, MPb′, MPc′, and MPd′ included in a embodiment of FIG. 6C are formed to have a size db greater than that of the metal plating layers MPa, MPb, MPc, and MPd of an embodiment of FIG. 6B. Even if the size db of the metal plating layers MPa′, MPb′, MPc′, and MPd′ in an embodiment of FIG. 6C is increased as compared to a size da of an embodiment of FIG. 6B, the conductive bumps 370′ (indicated by dotted lines) formed on the respective metal plating layers MPa′, Mpb′, MPc′, and MPd′ maintain sufficient space. The conductive bumps 370′ in an embodiment of FIG. 6C may also be formed to have a relatively large volume similar to the expanded metal plating layers MPa′, MPb′, MPc′, and MPd′. In an embodiment in which the conductive bumps 370 have a relatively large volume, a space to be filled by the non-conductive film may also be reduced between the semiconductor chips.

The expanded metal plating layers MPa′, MPb′, MPc′, and MPd′ may have an area larger than that of the metal plating layer on another pad, such as the non-merged pad. Further, the expanded metal plating layers MPa′, MPb′, MPc′, and MPd′ may be included, and thus the conductive bumps 370′ to be formed on the merged pad 140D′ may have a volume larger than the volume of a conductive bump on another pad, that is, the non-merged pad.

In the semiconductor package illustrated in embodiments of FIGS. 1 and 2, all the upper dumpy pads are provided as merged pads. However, embodiments of the present inventive concept are not necessarily limited hereto. For example, in an embodiment, only the upper dummy pads located in some areas may be introduced as merged pads, and the remaining upper dummy pads may be introduced as non-merged pads, e.g., single pads.

The space to be filled by the non-conductive film may be reduced by the introduction of the merged pad, and thus the merged pad may be selectively disposed in an area (e.g., a corner area) where filling is vulnerable among areas in which the upper dummy pads are arranged, as in an embodiment shown in FIG. 7, so that the non-conductive films may be uniformly filled over the entire area in the space between the semiconductor chips.

Referring to FIG. 7, the upper surface 100T of the semiconductor chip 100 that may be included in the semiconductor package is shown according to an embodiment. Upper pads are arranged on the upper surface 100T of the semiconductor chip 100, and include upper signal pads 140S located in the inner area IA and upper dummy pads 140D1 and 140D2 arranged in an area adjacent to the corner.

The upper dummy pads included in an embodiment of FIG. 7 include merged pads 140D1 configured to (e.g., arranged to) cover a plurality (e.g., four) of adjacent lower dummy pads among the lower dummy pads, and non-merged pads 140D2 configured to respectively correspond to other lower dummy pads among the second lower dummy pads. The non-merged pads 140D2 may be formed to have substantially the same size and shape as those of the upper signal pads 140S.

The four metal plating layers MPa, MPb, MPc, and MPd may be formed on the merged pads 140D1 to respectively correspond to the second lower dummy pads, and one metal plating layer MP may be disposed on each of upper surfaces of the non-merged pads 140D2, similar to the metal plating layers MP of the upper signal pads 140S.

In addition, the merged pads 140D1 may be disposed in corner areas adjacent to each corner of the upper surface of the semiconductor chip 100, and the non-merged pads 140D2 may be disposed between the corner areas on the upper surface of the semiconductor chip 100.

As described above, during a semiconductor chip stacking process, when the semiconductor chips are bonded by using a thermal compression bonding (TCB) method, a constant pressure may be applied to the non-conductive film located between the semiconductor chips. The pressure is applied radially from the center of the semiconductor chips (see indication of the arrow), and thus a filling amount of the non-conductive film may be less in the corner area which is a relatively far distance from the center than in a near corner area. In an embodiment shown in FIG. 7, the merged pads 140D1 are disposed in corner areas adjacent to each corner of the upper surface of the semiconductor chip 100, and thus a space to be filled may be reduced in the space on the corner area. As a result, uniform filling in the entire space may be provided between the semiconductor chips.

In an embodiment of FIG. 7, for convenience of explanation, an example of the arrangement of the upper pads is 6×6, but thousands to hundreds of thousands of pads may be arranged in a square or rectangular shape having various different arrangements.

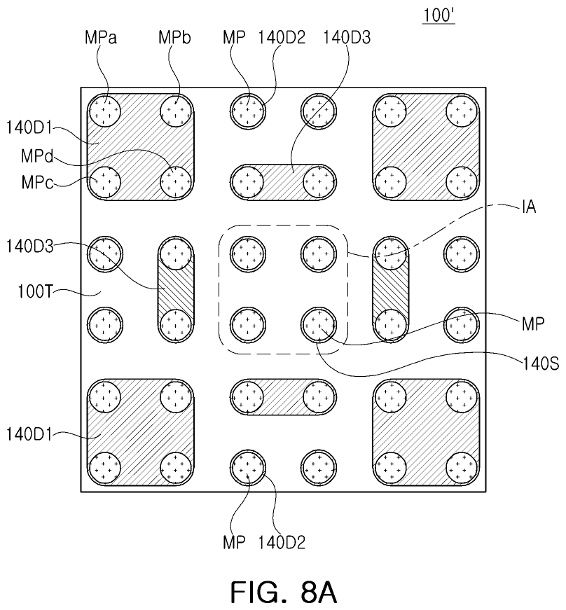

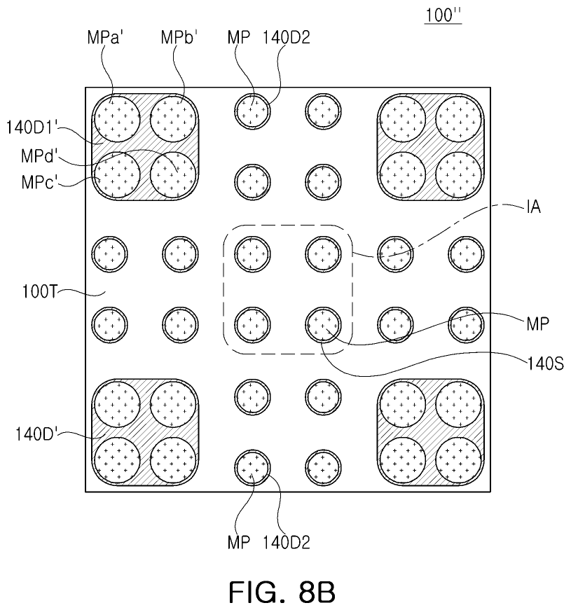

FIGS. 8A and 8B are plan views illustrating a semiconductor chip that may be employed in a semiconductor package according to various embodiments of the present inventive concept.

Referring to FIG. 8A, an arrangement of upper pads of a semiconductor chip 100′ according to an embodiment is illustrated.

Upper dummy pads included in an embodiment of FIG. 8A may include merged pads 140D1 and 140D3 and non-merged pads 140D2. As shown in an embodiment of FIG. 8, the merged pads may include two or more types of merged pads, such as the first and second merged pads 140D1 and 140D3.

Similar to an embodiment shown in FIG. 7, the first merged pad 140D1 may be configured to cover four adjacent lower dummy pads, and the second merged pad 140D3 may be configured to cover two adjacent lower dummy pads. The four metal plating layers MPa, MPb, MPc, and MPd may be formed on the first merged pads 140D1 to respectively correspond to the lower dummy pads, and the two metal plating layers MPa and MPb may be formed on upper surfaces of the second merged pads 140D3. In an embodiment shown in FIG. 8A, similar to an embodiment shown in FIG. 7, the first merged pad 140D1 may be arranged in a corner area, and the second merged pad 140D2 may be partially arranged in an area between the first merged pads 140D1.

Referring to FIG. 8B, an arrangement of upper pads of a semiconductor chip 100′ according to an embodiment is illustrated. Similar to an embodiment illustrated in FIG. 7, upper dummy pads included in an embodiment of FIG. 8B may, include the merged pads 140D1 and the non-merged pads 140D2.

However, the metal plating layers MPa′, MPb′, MPc′, and MPd′ formed on the merged pads 140D1 may be formed to have a size greater than that of the metal plating layers MPa, MPb, MPc, and MPd of an embodiment of FIG. 7. The conductive bumps 370′ formed on each of the metal plating layers MPa′, MPb′, MPc′, and MPd′ may also have a relatively large volume (see the description of FIG. 6C), and thus a space to be filled by the non-conductive film may be additionally reduced between the semiconductor chips.

As described above, in an embodiment of FIG. 8B, the merged pads 140D1 may additionally reduce the space to be filled in the space on the corner area, thereby more effectively providing uniform filling in the entire space between the semiconductor chips.

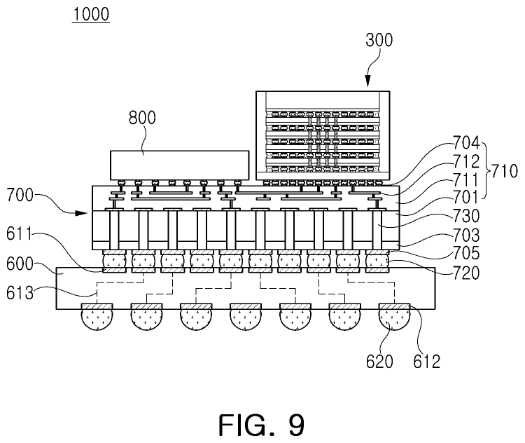

FIG. 9 is a cross-sectional view illustrating a semiconductor package according to are embodiment of the present inventive concept. The semiconductor package according to an embodiment of FIG. 9 may be understood as a module in which the semiconductor package shown in FIG. 1 is introduced as a chip stack structure (e.g., HBM).

Referring to FIG. 9, a semiconductor package 1000 according to an embodiment may include a package substrate 600, an interposer substrate 700, and the semiconductor package 300 of FIG. 1 (hereinafter, referred to as a chip stack structure). In addition, the semiconductor package 1000 may further include a logic chip or a processor chip 800 disposed adjacent to the chip stack structure 300 on the interposer substrate 700.

The package substrate 600 may include a lower pad 612 disposed on a lower surface of a body, an upper pad 611 disposed on an upper surface of the body, and a redistribution circuit 613 electrically connecting the lower pad 612 and the upper pad 611. The package substrate 600 is a support substrate on which the interposer substrate 700, the logic chip 800, and the chip stack structure 300 are mounted, and may be a substrate for a semiconductor package including a printed circuit board (PCB), a ceramic substrate, a glass substrate, a tape wiring board, etc. The body of the package substrate 600 may include different materials according to the type of a substrate. For example, when the package substrate 600 is a PCB, the package substrate 600 may have a structure in which a wiring layer is additionally stacked on one surface or both surfaces of a body copper stack plate or a copper stack plate. A solder resist layer may be formed on each of a lower surface and an upper surface of the package substrate 600. The lower and upper pads 612 and 611 and the redistribution circuit 613 may form an electrical path connecting the lower surface and the upper surface of the package substrate 600.

The upper pad 611, the lower pad 612, and the redistribution circuit 613 may include an alloy including at least one metal or two or more metals of metal materials such as copper (Cu), aluminum (Al), nickel (Ni), silver (Ag), or gold (Au), platinum (Pt), tin (Sn), lead (Pb), titanium (Ti), chromium (Cr), palladium (Pd), indium (In), zinc (Zn), and carbon (C). However, embodiments of the present inventive concepts are not necessarily limited thereto. The redistribution circuit 613 may include redistribution layers of a multilayer structure and vias connecting the redistribution layers. An external connection terminal 620 connected to the lower pad 612 may be disposed on the lower surface of the package substrate 600, in an embodiment, the external connection terminal 620 may include tin (Sn), indium (In), bismuth (Bi), antimony (Sb), copper (Cu), silver (Ag), zinc (Zn), lead (Pb) and/or alloys thereof.

The interposer substrate 700 may include a substrate 701 a lower protective layer 703, a lower pad 705, an interconnection structure 710, a metal bump 720, and a through via 730. The chip stack structure 300 and the processor chip 800 may be stacked on the package substrate 600 via the interposer substrate 700. The interposer substrate 700 may electrically connect the chip stack structure 300 and the processor chip 800 to each other. In an embodiment, the substrate 701 may be formed of, for example, any one of silicon, an organic material, plastic, and a glass substrate. For example, in an embodiment of FIG. 9, the interposer substrate 700 may be a silicon interposer.

The lower protective layer 703 may be disposed on a lower surface of the substrate 701, and a lower pad 705 may be disposed on the lower protective layer 703. The lower pad 705 may be connected to the through via 730. The chip stack structure 300 and the processor chip 800 may be electrically connected to the package substrate 600 through the metal bumps 720 disposed on the lower pad 705.

The interconnection structure 710 may be disposed on an upper surface of the substrate 701, and may include an interlayer insulating layer 711 and a single-layer or multi-layer wiring structure 712. In an embodiment in which the interconnection structure 710 has the multi-layer wiring structure, wiring patterns of different layers may be connected to each other through contact vias.

The through via 730 may extend from the upper surface to the lower surface of the substrate 701 to penetrate through the substrate 701. In addition, the through via 730 may extend into the interconnection structure 710 to be electrically connected to the wirings of the interconnection structure 710. In an embodiment in which the substrate 701 is silicon, the through via 730 may be referred to as a TSV. In some embodiments, the interposer substrate 700 may include only the interconnection structure therein, and may not include a through via.

The interposer substrate 700 may be used for the purpose of converting or transferring an input electrical signal between the package substrate 600 and the chip stack structure 300 or the processor chip 800. Accordingly, the interposer substrate 700 may not include an element such as an active element or a passive element. In some embodiments, the interconnection structure 710 may be disposed in a lower portion of the through via 730.

The metal bump 720 may be disposed on the lower surface of the interposer substrate 700 and may be electrically connected to the wirings of the interconnection structure 710. The interposer substrate 700 may be stacked on the package substrate 600 through the metal bump 720. The metal bump 720 may be connected to the lower pad 705 through the wirings of the interconnection structure 710 and the through via 730. In an embodiment, some of the lower pads 705 used for power or ground may be integrated and connected together to the metal bump 720, and thus the number of the lower pads 705 may be greater than that of the metal bumps 720.

As described above, the logic chip or processor chip 800 may include, for example, a central processor (CPU), a graphics processor (GPU), a field programmable gate array (FPGA), a digital signal processor (DSP), a cryptographic processor, a microprocessor, a microcontroller, an analog-to-digital converter, an application-specific IC (ASIC), etc. According to types of devices included in the logic or processor chip 800, the semiconductor package 1000 may be a server-oriented semiconductor package or a mobile-oriented semiconductor package.

The semiconductor package 1000 according to an embodiment may further include an internal sealing material covering side surfaces and upper surfaces of the semiconductor package 1000 and the processor chip 800 on the interposer substrate 700. In addition, the semiconductor package 1000 may further include an external sealing material covering the interposer substrate 700 and the internal sealing material on the package substrate 600. The external sealing material and the internal sealing material may be formed together and thus may not be distinguished from each other. In some embodiments, the semiconductor package 1000 may further include a heat sink covering the chip stack structure 300 and the processor chip 800 on the package substrate 600.

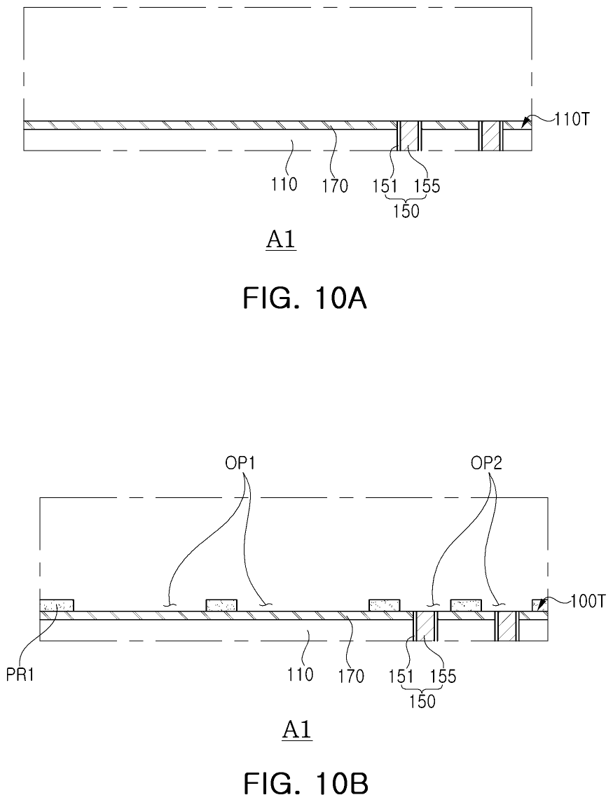

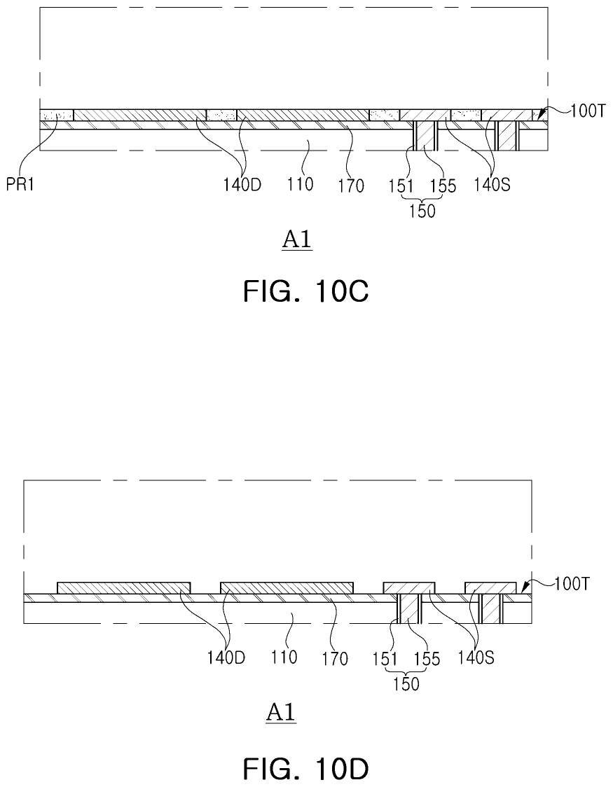

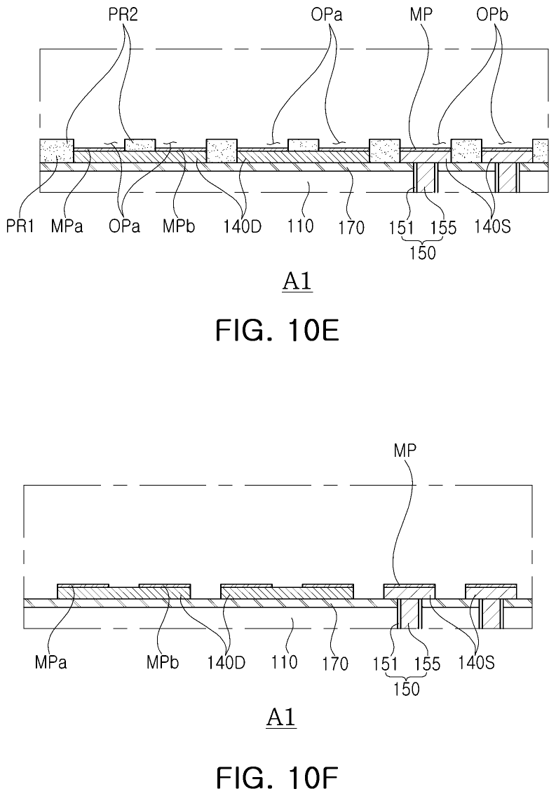

FIGS. 10A to 10F are cross-sectional views for explaining a method of manufacturing a semiconductor package according to embodiments of the present inventive concept for each main process. The manufacturing method according to the embodiments of FIGS. 10A to 10F may be understood as a manufacturing process of the semiconductor package shown FIGS. 1 to 5.

Referring to an embodiment of FIG. 10A, after the upper insulating layer 170 is formed, grinding may be performed so that an upper end of the through electrode 150 is exposed.

A grinding process for reducing the thickness of a semiconductor substrate may be performed before forming an upper insulating layer. The upper insulating layer 170 may be used as a passivation layer. For example, the upper insulating layer 170 may include silicon nitride or silicon oxynitride. Next, a plating seed layer may be formed on the upper insulating layer 170.

Referring to an embodiment of FIG. 10B, a first photoresist pattern PR1 for forming an upper pad 140 (FIGS. 1 and 2) may be formed on the upper insulating layer 170.

The first photoresist pattern PR1 may include a first opening OP1 for the upper dummy pad 140D (FIGS. 1 and 2) and a second opening OP2 for the upper signal pad 140S (FIGS. 1 and 2). In an embodiment, the first opening OP1 may have an area larger than that of the second opening OP2. In a plan view, the first photoresist pattern PR1 may have a pattern in which the openings OP1 and OP2 respectively corresponding to the pads 140D and 140S shown in an embodiment of FIG. 2 are arranged.

In an embodiment of FIG. 10B, the second opening OP2 may be formed to have an area and a location corresponding to a single pad (e.g., one lower signal pad), and the first opening OP1 may be formed to have an area and a location covering a plurality of adjacent single pads (e.g., two adjacent lower dummy pads).

Referring to an embodiment of FIG. 10C, the upper pads 140D and 140S may be formed using the first photoresist pattern PR1, and referring to an embodiment of FIG. 10D, the first photoresist pattern PR1 may be removed.

The present process may be implemented through an electrolytic plating process. For example, in an embodiment, the upper pads 140D and 140S may include copper or nickel. Through the present process, the upper dummy pad 140D that is a merged pad may be formed in the first opening OP1, and the upper signal pad 140S connected to the through electrode 150 may be formed in the second opening. In an embodiment, the first photoresist pattern PR1 may be removed using a strip process, and an exposed part of a plating seed layer may be removed by etching.

Referring to an embodiment of FIG. 10E, a second photoresist pattern PR2 including third and fourth openings OPa and OPb for the metal plating layer may be formed on the upper surface of the semiconductor chip 100 on which the upper pads 140D and 140S are formed.

The third openings OPa located on the upper dummy pads 140D may be formed to respectively correspond to adjacent second lower dummy pads, and the fourth openings OPb located on the upper signal pads 140S may be formed to open substantially the entire area of the corresponding pad. The third openings OPa formed in the present embodiment are provided as two openings separated from each of the upper dummy pads 140D. In addition, the size of the third opening OPa may be adjusted, and thus the size of the metal plating layers MPa and MPb (FIG. 10F) to be formed on the upper dummy pads 140D may be adjusted.

Referring to an embodiment of FIG. 10F, the metal plating, layers MPa, MPb, and MP may be formed using the second photoresist pattern PR2, and the second photoresist pattern PR2 may be removed.

The metal plating layers MPa, MPb, and MP may be formed by an electrolytic plating process. For example, in an embodiment, the metal plating layers MPa, MPb, MP may include a plating layer such as Au. Each of the metal plating layers MPa, MPb, and MP formed as described above may define a joint area by the conductive bump 370 in a pad area. In an embodiment, a seed layer for electroplating may be used as a seed layer in the present process without removing the seed layer formed in the step of FIG. 10A after the process of FIG. 10D. In this embodiment, after the second photoresist pattern PR2 is removed, an exposed part of the seed layer may be removed by etching.

The present in concept is not limited by the above-described embodiments and the accompanying drawings. Accordingly, various types of substitutions, modifications and alterations and combinations of example embodiments will be possible by those of ordinary skill in the art within the scope not departing from the technical spirit of the present inventive concept.

The dummy pad is implemented in a structure in which the plurality of dummy pads are merged, and thus the area of a metal element having excellent thermal conductivity between semiconductor chips may be increased, and as a result, the heat dissipation characteristics of the semiconductor package may be increased. In addition, the space to be filled may be reduced by selectively disposing the merged dummy pad (also referred to as the ‘merged pad’) in an area (e.g., a corner area) where filling by the non-conductive film is vulnerable, and thus uniform filling may be provided over the entire space between the first and second semiconductor chips.

Various advantages and effects of the present inventive concept are not limited to the description above.

What is claimed is:

1. A semiconductor package comprising:
a first semiconductor chip having an upper surface including first upper signal pads and first upper dummy pads disposed thereon, a lower surface including first lower signal pads and first lower dummy pads disposed thereon, and first through electrodes electrically connecting the first upper signal pads and the first lower signal pads;
a second semiconductor chip disposed on the first semiconductor chip, the second semiconductor chip having an upper surface including second upper signal pads and second upper dummy pads disposed thereon, a lower surface including second lower signal pads and second lower dummy pads disposed thereon and second through electrodes electrically connecting the second upper signal pads and the second lower signal pads;
first conductive bumps respectively disposed between the first upper signal pads and the second lower signal pads; and
second conductive bumps respectively disposed between the first upper dummy pads and the second lower dummy pads,
wherein the first upper dummy pads include merged pads covering a plurality of adjacent second lower dummy pads among the second lower dummy pads and
wherein a plurality of first metal plating layers are disposed on an upper surface of each of the merged pads in areas respectively corresponding to the plurality of adjacent second lower dummy pads, and the second conductive bumps include a plurality of conductive bumps respectively disposed between the plurality of first metal plating layers and the plurality of adjacent second lower dummy pads.

2. The semiconductor package of claim 1, wherein the first upper dummy pads are arranged in an area adjacent to a corner of the upper surface of the first semiconductor chip.

3. The semiconductor package of claim 2, wherein the first upper signal pads are disposed in an inner area of the upper surface of the first semiconductor chip.

4. The semiconductor package of claim 1, wherein:
each of the merged pads covers two adjacent second lower dummy pads among the second lower dummy pads; and
two first metal plating layers are disposed on an upper surface of each of the merged pads in an area corresponding to each of the two adjacent second lower dummy pads.

5. The semiconductor package of claim 1, wherein:
each of the merged pads is configured to cover four second lower dummy pads arranged in a square among the second lower dummy pads; and
four first metal plating layers are disposed on an upper surface of each of the merged pads in an area corresponding to each of the four second lower dummy pads.

6. The semiconductor package of claim 1, further comprising a non-conductive adhesive layer disposed between the first semiconductor chip and the second semiconductor chip and surrounding each of the first and second conductive bumps.

7. The semiconductor package of claim 6, wherein the first upper dummy pads include non-merged pads that each respectively cover only one of the second lower dummy pads.

8. The semiconductor package of claim 7, wherein the merged pads are disposed in corner areas adjacent to each corner of the upper surface of the first semiconductor chip.

9. The semiconductor package of claim 8, Wherein the non-merged pads are disposed between the corner areas on the upper surface of the first semiconductor chip.

10. The semiconductor package of claim 1, wherein:
the first upper dummy pads comprise non-merged pads that each respectively cover only one of the second lower dummy pads; and
a second metal plating layer is disposed on an upper surface of each of the non-merged pads.

11. The semiconductor package of claim 10, wherein each of the plurality of first metal plating layers has an area larger than an area of the second metal plating layer.

12. The semiconductor package of claim 11, wherein:
the second conductive bumps comprise third conductive bumps on the merged pads and fourth conductive bumps on the non-merged pads; and
each of the fourth conductive bumps on the merged pads has a volume larger than a volume of the third conductive bump on the non-merged pad.

13. The semiconductor package of claim 1, wherein all of the first upper dummy pads are merged pads.

14. The semiconductor package of claim 1, further comprising:
a third semiconductor chip disposed on the second semiconductor chip and comprising a lower surface including third lower signal pads and third lower dummy pads disposed thereon;
third conductive bumps respectively disposed between the second upper signal pads and the third lower signal pads; and
fourth conductive bumps respectively disposed between the second upper dummy pads and the third lower dummy pads,
wherein the second upper dummy pads comprise additional merged pads covering a plurality of adjacent third lower dummy pads among the third lower dummy pads, and
wherein a plurality of third metal plating layers are disposed on an upper surface of each of the additional merged pads in areas respectively corresponding to the plurality of adjacent third lower dummy pads, and the fourth conductive bumps comprise a plurality of conductive bumps respectively disposed between the plurality of third metal plating layers and the plurality of adjacent second lower dummy pads.

15. A semiconductor package comprising:
a first semiconductor chip comprising an upper surface including upper signal pads and upper dummy pads disposed thereon, a lower surface including first lower signal pads and first lower dummy pads disposed thereon, and through electrodes electrically connecting the upper signal pads and the first lower signal pads;
a second semiconductor chip disposed on the first semiconductor chip, and comprising a lower surface including second lower signal pads and second lower dummy pads disposed thereon;
conductive bumps respectively disposed between the upper signal pads and the second lower signal pads and respectively disposed between the upper dummy pads and the second lower dummy pads; and
a non-conductive adhesive layer disposed between the first semiconductor chip and the second semiconductor chip and surrounding the conductive bumps,
wherein the upper dummy pads comprise merged pads covering a plurality of adjacent second lower dummy pads among the second lower dummy pads and non-merged pads respectively covering only one second lower dummy pad among the second lower dummy pads, and
wherein the merged pads are disposed in corner areas adjacent to each corner of the upper surface of the first semiconductor chip, and the non-merged pads are disposed between the corner areas on the upper surface of the first semiconductor chip.

16. The semiconductor package of claim 15, wherein:
a plurality of first metal plating layers are disposed on an upper surface of each of the merged pads in areas respectively corresponding to the plurality of adjacent second lower dummy pads, and only one second metal plating layer is disposed on an upper surface of each of the non-merged pads.

17. The semiconductor package of claim 16, wherein each of the plurality of first metal plating layers has an area larger than an area of the second metal plating layer.

18. The semiconductor package of claim 16, wherein:
the conductive bumps comprise a plurality of first conductive bumps respectively disposed on the plurality of first metal plating layers and respectively connected to the plurality of adjacent second lower dummy pads and a second conductive bump disposed on the second metal plating layer and connected to a corresponding second lower dummy pad.

19. The semiconductor package of claim 18, wherein each of the plurality of first conductive bumps has a volume larger than a volume of the second conductive bump.

20. A semiconductor package comprising:
first and second substrates that are vertically stacked;
a semiconductor device layer disposed on a lower surface of the second substrate and facing an upper surface of the first substrate;
through electrodes penetrating through the second substrate and respectively connected to the upper signal pads;
lower signal pads disposed on a lower surface of the semiconductor device layer and electrically connected to the through electrodes, respectively;
lower dummy pads disposed on the lower surface of the semiconductor device layer;
upper signal pads disposed on the upper surface of the first substrate and arranged to correspond to each of the lower signal pads;
upper dummy pads disposed on the upper surface of the first substrate and respectively covering a plurality of adjacent lower dummy pads among the lower dummy pads;
a plurality of metal plating layers disposed in areas respectively corresponding to the plurality of adjacent lower dummy pads in the respective upper dummy pads;
first conductive bumps electrically connecting the lower signal pads and the upper signal pads, respectively; and
second conductive bumps respectively disposed on the plurality of metal plating layers of the respective upper dummy pads and respectively connected to the lower dummy pads.
